(19) United States
(12) Patent Application Publication
(10) Pub. No.: US 2020/0209188 A1
(43) Pub. Date: Jul. 2, 2020

(54) STABLE AND SELECTIVE HUMIDITY DETECTION USING RANDOMLY STACKED BLACK PHOSPHORUS FLAKES

(71) Applicant: Board of Trustees of the University of Illinois, Urbana, IL (US)

(72) Inventors: Amin Salehi-Khojin, Chicago, IL (US); Poya Yasaei, Chicago, IL (US); Fatemeh Khalili-Araghi, Chicago, IL (US)

(21) Appl. No.: 15/752,206

(22) PCT Filed: Aug. 11, 2016
(86) PCT No.: PCT/US2016/046521

§ 371 Date: Feb. 12, 2018

Related U.S. Application Data
(60) Provisional application No. 62/203,440, filed on Aug. 11, 2015.

(51) Int. Cl. G01N 27/414; G01N 27/12

(52) U.S. Cl. CPC G01N 27/4146; H01L 29/24; G01N 27/121; G01N 27/4141

(57) ABSTRACT

The present disclosure relates to the use of black phosphorus nanoflakes in humidity sensing and transistor applications. More particularly, the present disclosure relates to humidity sensing devices comprising black phosphorus nanoflakes, to methods for sensing humidity with such devices, to transistors comprising black phosphorus nanoflakes, and to methods for switching the gate of such transistors. In one aspect, the disclosure provides a device for sensing moisture, the device including a substrate; and a surface including at least one atomic layer of black phosphorus nanoflakes disposed on the substrate, wherein the sensing device is specific to sensing humidity, exhibiting a selective response against water vapor.

### CROSS-REFERENCE TO RELATED APPLICATIONS

This application claims the benefit of priority of U.S. Provisional Patent Application no. 62/203,440, filed Aug. 11, 2015, which is hereby incorporated herein by reference in its entirety.

### BACKGROUND OF THE DISCLOSURE

### Field of the Disclosure

This disclosure relates generally to humidity sensing devices. More particularly, the present disclosure relates to humidity sensing devices comprising black phosphorus nanoflakes, to methods for sensing humidity with such devices, to transistors comprising black phosphorus nanoflakes, and to methods for switching the gate of such transistors.

### Technical Background

Black phosphorus (BP) is the most thermodynamically stable allotrope of phosphorus, and has an orthorhombic layered structure and highly anisotropic properties. Due to its high charge carrier mobility, tunable direct bandgap, large on/off ratios (>10⁵), and anisotropic properties, BP has potential for use in electronics and optoelectronics. The potential uses for BP in further applications such as energy generation, storage systems, and electrocatalysis have also been demonstrated. However, the material has yet to be demonstrated to be appropriate for long-term applications, in view of the observed ambient instability of atomically thin BP flakes.

Humidity control is important in a variety of different applications, including industrial processes, environmental applications, electronic and biotechnology applications, agriculture, libraries and household applications. Semiconductor manufacturing and certain medical applications, including respiratory equipment, sterilizers, incubators, pharmaceutical processing, and the manufacture of biological products all require controlled humidity. Chemical gas purification, film desiccation, paper and textile production and food processing also may require controlled humidity.

Recently, an increasing demand has developed for low-cost humidity sensors with accuracy, reproducibility, and long-term stability. However, good humidity sensors are generally expensive. Many inexpensive sensors do not perform well at either extreme of relative humidity (RH).

Accordingly, there remains a need for a cost-effective humidity sensor that is accurate, reliable, and stable.

### SUMMARY OF THE DISCLOSURE

One aspect of the disclosure is a device for sensing moisture, the device including
a substrate; and
a surface comprising at least one atomic layer of black phosphorus nanoflakes disposed on the substrate,
   wherein the sensing device is specific to sensing humidity, exhibiting a selective response against water vapor. For example, in certain embodiments as disclosed herein, a device for sensing moisture includes
a substrate;
a surface comprising at least one atomic layer of black phosphorus nanoflakes disposed on the substrate, the at least one atomic layer of black phosphorus nanoflakes being in fluid communication with the exterior of the device;
a first electrode disposed in electrical contact with the at least one atomic layer of black phosphorus nanoflakes;
a second electrode disposed in electrical contact with the at least one atomic layer of black phosphorus nanoflakes;
a voltage source configured to apply a voltage across the first electrode and the second electrode sufficient to cause a drain current to flow through the at least one atomic layer of black phosphorus nanoflakes, the drain current having a magnitude; and
electronics configured to detect the magnitude of the drain current.

Another aspect of the disclosure is a transistor that includes
a substrate;
a surface comprising a film of stacked black phosphorous nanoflakes disposed on the substrate; and
a gate.
   The person of ordinary skill in the art will appreciate, however, that in certain embodiments, the “gate” function of the transistor is the action of humidity on the film of black phosphorus nanoflakes, such that the film of black phosphorus nanoflakes allows more current to flow as the humidity is increased (i.e., due to a decrease in resistance in the film as humidity decreases). Accordingly, in other aspects of the disclosure, a transistor includes
a substrate;
a surface comprising a film of stacked black phosphorous nanoflakes disposed on the substrate; and
at least two electrodes comprising a first electrode and a second electrode, disposed in electrical contact with the film of stacked black phosphorus nanoflakes,
wherein the transistor is configured such that the electrical resistance between the first electrode and the second electrode decreases with an increase in humidity.

Another aspect of the disclosure is a humidity sensor that includes
a sensor chamber having an opening; and
a humidity sensing device as described herein;
wherein the device is disposed within the chamber, and the chamber is in fluid communication with the opening.

Another aspect of the disclosure is a method for sensing moisture in an environment, the method including
providing a humidity sensing device as described herein;
applying a voltage across a first electrode and a second electrode sufficient to cause a drain current to flow through the at least one atomic layer of black phosphorus nanoflakes, the drain current having a magnitude; and
detecting the magnitude of the drain current.
   The method can further include determining a moisture level in the environment based on the magnitude of the drain current.

Another aspect of the disclosure is a method for switching a transistor, the method including
providing a transistor as described herein in fluid communication with an environment with a moisture level;
applying a voltage across the first electrode and the second electrode sufficient to cause a drain current to flow through the film of stacked black phosphorus nanoflakes, the drain current having a magnitude; and
allowing the level of moisture to change sufficiently to alter the magnitude of the drain current.

### BRIEF DESCRIPTION OF THE DRAWINGS

FIG. 1 is a schematic cross-sectional view of a device 100 including a substrate 110 and a layer of black phosphorus nanoflakes (BP NF) 120.

FIG. 2 is a schematic cross-sectional view of a device 200 comprising a substrate 210, a layer of BP NF 220, and electrodes 230, disposed below layer 220 and above substrate 210.

FIG. 3 is a schematic cross-sectional view of a device 300 comprising a substrate 310, a layer of BP NF 320, electrodes 330, and a voltage source 340.

FIG. 4 is a schematic cross-sectional view of a device 400 comprising a substrate 410, a layer of BP NF 420, electrodes 430, a voltage source 440, and electronics 450.

FIG. 5 is a set of photographs demonstrating the fabrication process of a BP NF film device from prepared BP dispersions as described in more detail in Example 1, below. This process starts with vacuum filtration of solution on a PTFE filter followed by properly rinsing and drying under vacuum; FIG. 5A is a photographic top view of the PTFE filter with a BP NF film disposed thereon. The filter is then cut into desired sizes. FIG. 5B is a top photographic view of a cut piece of the BP NF nanoflake/PTFE filter structure. The cut piece is disposed on a tape for mechanical support and ease of handling, and electrical connections are established by applying Ga—In eutectic. FIG. 5C is a top photographic view of the resulting device.

FIG. 6A is a set of photographs of black phosphorus in dispersion and in a film, as described in more detail in Example 1, below. FIG. 6A is a photograph of a BP dispersion in DMF solvent after sonication. FIG. 6B is a photograph of the BP dispersion of FIG. 6A after centrifugation and supernatant collection. FIG. 6C is an optical image of a film of stacked BP nanoflakes prepared by vacuum filtration on a PTFE membrane.

FIG. 7 is a set of SEM images of black phosphorus nanoflake films. FIG. 7A is a scanning electron microscopy (SEM) image of the filtered nanoflake films, showing the tightly stacked structure of the film. The scale bar is 2 μm. FIG. 7B is an SEM image of the film cross-section. The scale bar is 20 μm.

FIG. 8 is a representative Raman point spectrum obtained from a vacuum filtered film, as described in more detail below in Example 2.

FIG. 9 is a graph showing the current response of the stacked BP NF device to different analytes as described in more detail in Example 3, below. The curves have the same baseline, but are offset for clarity, showing, in top-to-bottom order, water, ethanol, toluene, dichlorobenzene, hydrogen, and oxygen. The inset (right) magnifies the same curves except for water, in the same top-to-bottom order.

FIG. 10 is a set of images providing a comparison of the BP film sensors described herein to those made using chemical vapor deposited (CVD) and liquid exfoliated graphene and MoS₂ films, as described in more detail below in Example 4. FIG. 10A is a microscope image of a partially CVD-grown film of graphene with hexagonal shape. FIG. 10B is a microscope image of a full, continuous film of graphene, grown at a longer growth time than the partial film of FIG. 10A. FIGS. 10C and 10D are respectively partial- and full-coverage films of MoS₂ , prepared via atmospheric pressure CVD using MoO₃ and sulfur precursors at different growth times, similar to previously reported recipes (see Van der Zande et al., “Grains and Grain Boundaries in Highly Crystalline Monolayer Molybdenum Disulphide,” Nat. Mater. 12:554-61 (2013); Najmei et al., “Vapour Phase Growth and Grain Boundary Structure of Molybdenum Disulphide Atomic Layers,” Nat. Mater. 12:754-9 (2013), each of which is hereby incorporated herein by reference in its entirety). FIGS. 10E, 10F and 10G are microscope images of films of, respectively, BP NFs, of graphene and MoS₂, prepared via similar liquid exfoliation techniques. FIG. 10H is a picture of three example devices.

FIG. 11 is a graph of sensitivity vs. reciprocal of recovery time (1/T) for 4 different BP NF devices upon exposure to different concentrations of water vapor in identical experimental conditions, as described in more detail below in Example 4. The error bars represent the standard deviation of multiple experiments.

FIG. 12 is a graph of the current of a typical BP NF device vs. relative humidity (RH) at 25° C., as described in more detail below in Example 4. The inset is a schematic view of the custom-made chamber that was used for the experiment.

FIG. 13 is a set two graphs showing the effect of temperature on the response of the BP NF device in an isolated environment, as described in more detail below in Example 5. The upper plot shows the RH (closed squares) and temperature (open circles) obtained from a reference sensor as a function of time. The lower plot shows the calculated absolute humidity (a, closed squares) and the response of the device (I, open circles). This plot shows that the sensor is only sensitive to the absolute humidity and is almost insensitive to temperature.

FIG. 14 is a set of graphs showing the pressure response of the BP NF device under a variety of conditions, as described above with respect to Example 5. FIG. 14A is a graph of the response (I, continuous line) of the sensor and the actual pressure (Ref. Press., filled circles joined by line) in the transient time of evacuating and refilling the vacuum chamber. The pressure is measured by a reference digital vacuum gauge. FIG. 14B is a graph of the response of the sensor with respect to pressure at initial humidity levels of 27% and 67%. The sensor is sensitive to changes in the pressure for a broad range of 10⁻⁵ to 10³ mbar.

FIG. 15 is a set of graphs demonstrating the response of black phosphorus under various conditions, as described below in Example 6. FIG. 15A is a graph comparing the responses of an individual mechanically exfoliated BP flake and a film of stacked BP NFs upon exposure to a pulse of water vapor. The response of the mechanically exfoliated flake is multiplied by 10 for clarity. FIG. 15B is a graph of the current-voltage (I-V) characteristics of a representative BP NF device at different scan rates.

FIG. 16 is a set of graphs (16A-16D) showing the I-V characteristics of a BP NF film sensor at different RH in several different scan rates, as described below in Example 6.

FIG. 17 is a set of graphs showing device performance under various conditions, as described below in Example 6. FIG. 17A is a graph of I at V=0 as a function of scan rate in log-log format. FIG. 17B is a graph of the exponential current decay in a BP NF device at two different relative humidities (RHs).

FIG. 18 is a set of graphs showing device performance under various conditions, as described below in Example 6. FIG. 18A is a plot of impedance spectroscopy (IS) results obtained from a typical BP film sensor at different RH at 25° C. in a frequency range of −300 Hz to 10 MHz. The inset magnifies the same plot. FIG. 18B is a plot of extracted resistance and capacitance values of the tested BP NF devices, with respect to RH.

FIG. 19 is a set of AFM data for BP NF flakes under various conditions, as described below in Example 7. FIG. 19A is a series of AFM height images of two selected BP NF flakes with different times of exposure of a saturated humidity environment at 25° C. The scale bars are 5 μm. FIG. 19B is a set of line profiles (a-f) corresponding to the lines (a-f) drawn in FIG. 19A.

FIG. 20 is a set of graphs demonstrating time-stability of the BP NF sensors, as described below in Example 7. FIG. 20A is a plot of the sensing response of the liquid exfoliated sensor upon exposure to multiple injections of water vapor immediately after preparation and after 3 month exposure to ambient conditions, showing no noticeable change in sensitivity. The single asterisk peaks are of the response data trace collected immediately after preparation, and the double asterisk peaks are of the response data trace The responses are drawn with offset for clarity. FIG. 20B is a plot of the drift of the sensor under prolonged exposure to 35% and 83% RH at 25° C.

FIG. 21 is a set of graphs demonstrating performance of the BP NF sensors under various conditions, as described below in Example 7. FIG. 21A is a plot of the temperature response of BP NF devices under vacuum. FIG. 21B is photographic image showing the experimental setup used to test the effects of bending on BP NF devices. FIG. 21C is a plot of the strain-dependent current of a film of randomly stacked BP NF at constant V_{SD}=3 V.

FIG. 22 is a set of graphs demonstrating the effect of applied bias on a BP NF device performance, as described below with respect to Example 8. FIG. 22A is plot of base current vs. applied bias. FIG. 22B is a plot of maximum current vs. applied bias. FIG. 22C is a plot of sensitivity vs. applied bias.

### DETAILED DESCRIPTION

The particulars shown herein are by way of example and for purposes of illustrative discussion of the preferred embodiments of the present invention only and are presented in the cause of providing what is believed to be the most useful and readily understood description of the principles and conceptual aspects of various embodiments of the invention. In this regard, no attempt is made to show structural details of the invention in more detail than is necessary for the fundamental understanding of the invention, the description taken with the drawings and/or examples making apparent to those skilled in the art how the several forms of the invention may be embodied in practice. Thus, before the disclosed processes and devices are described, it is to be understood that the aspects described herein are not limited to specific embodiments, apparati, or configurations, and as such can, of course, vary. It is also to be understood that the terminology used herein is for the purpose of describing particular aspects only and, unless specifically defined herein, is not intended to be limiting.

The terms “a,” “an,” “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

All methods described herein can be performed in any suitable order of steps unless otherwise indicated herein or otherwise clearly contradicted by context. The use of any and all examples, or exemplary language (e.g., “such as”) provided herein is intended merely to better illuminate the invention and does not pose a limitation on the scope of the invention otherwise claimed. No language in the specification should be construed as indicating any non-claimed element essential to the practice of the invention.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “above,” and “below” and words of similar import, when used in this application, shall refer to this application as a whole and not to any particular portions of the application.

As will be understood by one of ordinary skill in the art, each embodiment disclosed herein can comprise, consist essentially of or consist of its particular stated element, step, ingredient or component. As used herein, the transition term “comprise” or “comprises” means includes, but is not limited to, and allows for the inclusion of unspecified elements, steps, ingredients, or components, even in major amounts. The transitional phrase “consisting of” excludes any element, step, ingredient or component not specified. The transition phrase “consisting essentially of” limits the scope of the embodiment to the specified elements, steps, ingredients or components and to those that do not materially affect the embodiment.

Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques. When further clarity is required, the term “about” has the meaning reasonably ascribed to it by a person skilled in the art when used in conjunction with a stated numerical value or range, i.e. denoting somewhat more or somewhat less than the stated value or range, to within a range of ±20% of the stated value; ±19% of the stated value; ±18% of the stated value; ±17% of the stated value; ±16% of the stated value; ±15% of the stated value; ±14% of the stated value; ±13% of the stated value; ±12% of the stated value; ±11% of the stated value; ±10% of the stated value; ±9% of the stated value; ±8% of the stated value; ±7% of the stated value; ±6% of the stated value; ±5% of the stated value; ±4% of the stated value; ±3% of the stated value; ±2% of the stated value; or ±1% of the stated value.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements.

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Some embodiments of this invention are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Furthermore, numerous references have been made to patents and printed publications throughout this specification. Each of the cited references and printed publications are individually incorporated herein by reference in their entirety.

In closing, it is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

In various aspects and embodiments, the disclosure relates to devices comprising at least one atomic layer of black phosphorus nanoflakes disposed on a substrate. The disclosure demonstrates sensing devices comprising at least one atomic layer of black phosphorus nanoflakes disposed on a substrate to be selective for water and highly sensitive, with negligible drift over time.

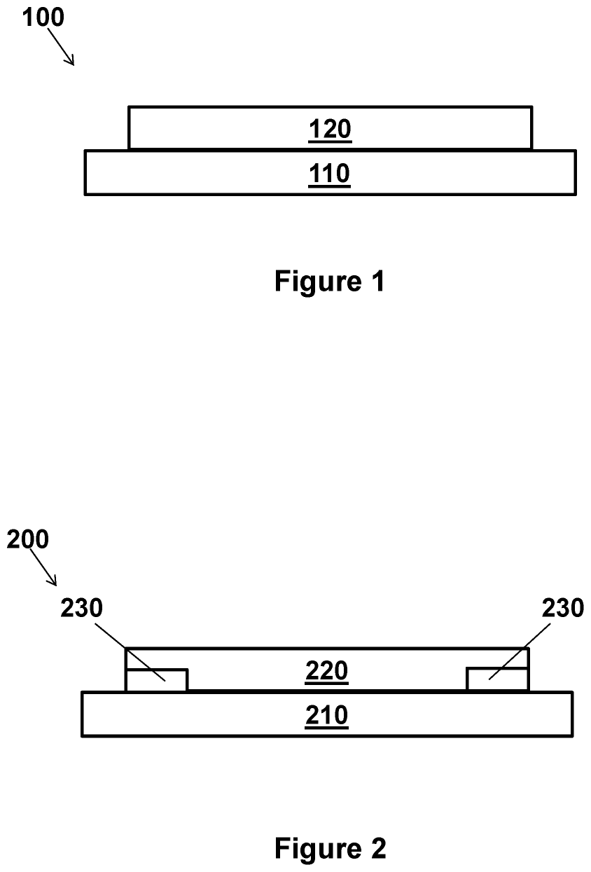

One aspect of the disclosure described herein is a device for sensing humidity comprising at least one atomic layer of black phosphorus nanoflakes (BP NF) disposed on a substrate. One example of such a device is shown in schematic view in FIG. 1. Device 100 includes a substrate 110 and a layer of BP NF 120 (i.e., at least one atomic layer of black phosphorus nanoflakes). The device may be specific to humidity. The device may utilize black phosphorous nanoflakes coupled with electrodes or electrical contacts. The black phosphorous nanoflakes may be formed into a film of stacked black phosphorous nanoflakes (i.e., of a plurality of atomic layers of black phosphorus nanoflakes). The sensing device may also include a voltage source. The device may also include a read-out system, particularly an electrical read-out. The device may be relatively unaffected by changes in temperature, i.e., exhibiting little temperature-based fluctuation and/or not drifting notably in different operating temperatures. The device may work well over a wide range of temperatures.

In some embodiments of the devices and methods as otherwise described herein, devices comprising BP NFs exhibit excellent sensitivity and selectivity for humidity sensing with quick recovery characteristics. In some embodiments, the at least one atomic layer of BP NFs may comprise stacks of BP NFs, i.e., a film of stacked BP NFs with a thickness within the range of 10 nm to 1000 μm, e.g., 25 nm to 1000 μm, or 50 nm to 1000 μm, or 75 nm to 1000 μm, or 100 nm to 900 μm, or 150 nm to 800 μm, or 200 nm to 700 μm, or 250 nm to 600 μm, or 500 nm to 500 μm, or 750 nm to 400 μm, or 1 μm to 300 μm, or 2 μm to 250 μm, or 3 μm to 200 μm, or 4 μm to 175 μm, or 5 μm to 150 μm.

In some embodiments of the devices and methods as otherwise described herein, the at least one atomic layer of BP NFs is in fluid communication with the exterior of the device.

While not being bound by theory, the impedance spectroscopy and electrical characterization of the Examples suggest that the sensing mechanism of the BP film sensors is based on the modulation in the leakage ionic current due to protonation of water molecules and phosphorus oxoacids in the presence of humidity. The degradation rate of the BP flakes in humid environments is estimated by consecutive atomic force microscopy (AFM) topography mappings and is found to be slow enough to allow for the use of BP NF devices in practical applications, with an effective lifetime of several years.

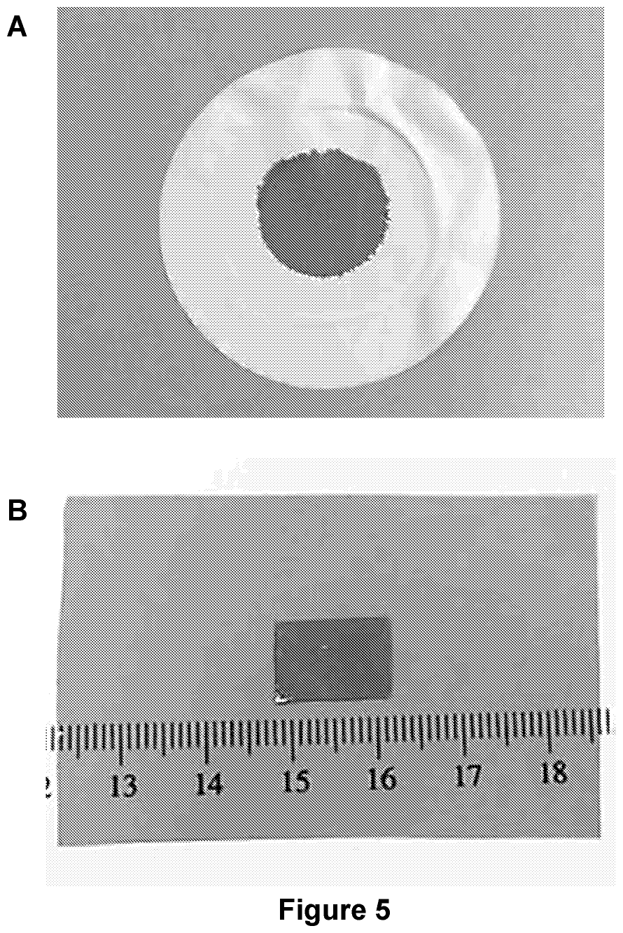

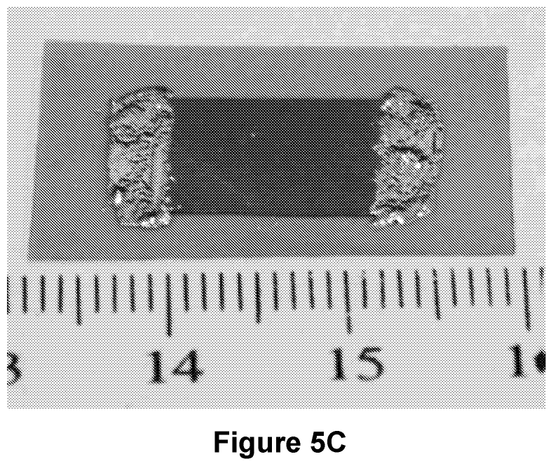

The person of ordinary skill in the art will appreciate that BP NF may be made by liquid exfoliation through ultra-sonication followed by vacuum filtration. In some embodiments of the devices and methods as otherwise described herein, the liquid exfoliation solvent for BP NF may be an aprotic, polar solvent, e.g., DMF, DMSO, and the like. In some embodiments, vacuum filtration may be performed using filter paper or a membrane filter, e.g., a PTFE membrane filter to form a layer of BP NF on a substrate. Following vacuum filtration, BP NF films may be rinsed and dried under vacuum, as described with respect to FIG. 5A. The person of ordinary skill in the art will appreciate that, after liquid exfoliation and vacuum filtration, the film may then be cut into desired sizes and stuck on a tape for mechanical support and ease of handling, as described with respect to FIG. 5B.

In some embodiments of the devices and methods as otherwise described herein, devices comprising BP NF are highly selective for moisture content in the environment, and are insensitive to other analytes such as alcohols, ketones, benzenes, etc. The person of ordinary skill in the art will appreciate the need to avoid cross-sensitivity and false-positive issues in practical moisture detection applications.

In some embodiments of the devices and methods as otherwise described herein, the substrate of the device may be flexible. In some embodiments, the substrate of the device may comprise filter paper or a membrane filter, e.g., a polytetrafluoroethylene (PTFE) membrane filter. This flexibility may allow the sensing devices to be flexible. The person of ordinary skill in the art will appreciate that flexible sensing devices may be used in wearable applications, such as wearable medical devices, environmental monitoring systems, military defense, homeland security, food processing units, etc.

In some embodiments of the devices and methods as otherwise described herein, the device may further comprise at least two electrodes, e.g., two electrodes, or three electrodes, or four electrodes, etc. In some embodiments, the at least two electrodes may be two-probe electrical contacts. The at least two electrodes are disposed in electrical contact with the at least one atomic layer of BP NF. One example of such a device is shown in schematic view in FIG. 2. Device 200 includes a substrate 210, a layer of BP NF 220, and electrodes 230, disposed below layer 220 and above substrate 210. As the person of ordinary skill in the art will appreciate, the at least two electrodes may be disposed in any of a number of arrangements in which each of the at least two electrodes and the at least one atomic layer of BP NF are in electrical contact, such as between the BP NF layer and the substrate, as shown in FIG. 2, or on top of the BP NF layer, as shown in FIG. 5C. A variety of suitable electrode materials are known in the art. In some embodiments, the at least two electrodes may be Gallium-Indium eutectic. In some embodiments, the at least two electrodes may comprise one or more of any suitable metal, e.g., gold, copper, zinc, tungsten, lead, silver, platinum, and palladium.

In some embodiments of the devices and methods as otherwise described herein, the at least two electrodes include a first electrode and a second electrode. In certain embodiments, the distance between the first electrode and the second electrode is less than 2 cm, e.g., less than 1.75 cm, or less than 1.5 cm, or less than 1 cm, or less than 900 μm, or less than 800 μm, or less than 700 μm, or less than 600 μm, or less than 500 μm, or less than 400 μm, or less than 300 μm, or less than 200 μm, or less than 100 μm, or less than 75 μm, or less than 50 μm, or less than 25 μm, or less than 15 μm, or less than 10 μm, or less than 8 μm, or less than 6 μm, or less than 5 μm, or less than 4 μm, or less than 3 μm, or less than 2 μm, or less than 1 μm.

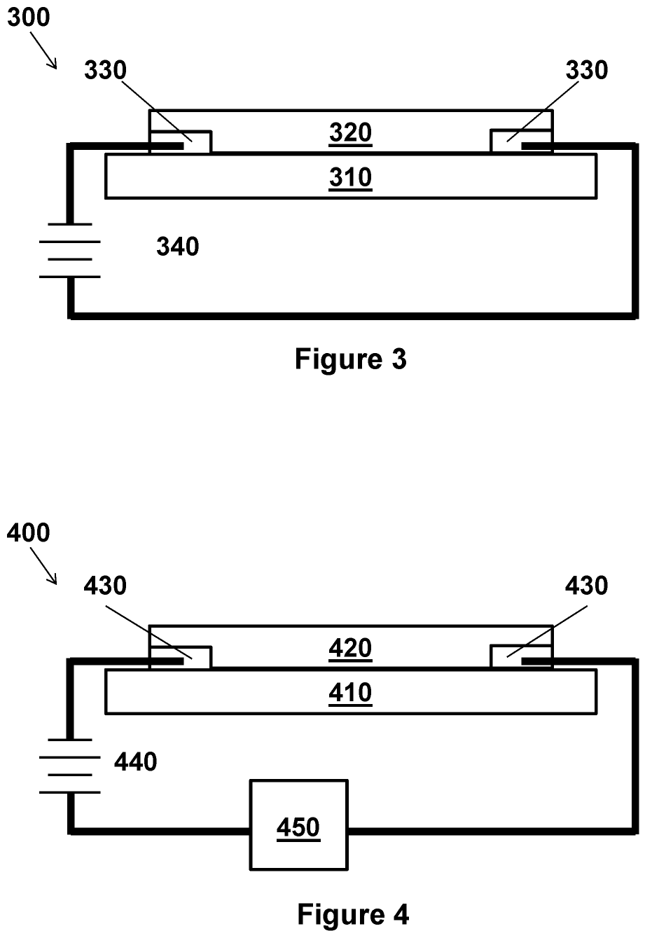

In some embodiments of the devices and methods as otherwise described herein, the at least two electrodes include a first electrode and a second electrode, and the device further comprises a voltage source configured to apply a voltage across the first electrode and the second electrode sufficient to cause a drain current to flow through the at least one atomic layer of BP NF, wherein the drain current has a magnitude. One example of such a device is shown in schematic view in FIG. 3. Device 300 includes a substrate 310, a layer of BP NF 320, electrodes 330, and a voltage source 340. In some embodiments, the voltage source is configured to apply a voltage within the range of about 0.01 V to about 4 V, e.g., about 0.01 V to about 3.5 V, or about 0.01 V to about 3 V, or about 0.01 V to about 2.5 V, or about 0.01 V to about 2 V, or about 0.01 V to about 1.75 V, or about 0.01 V to about 1.5 V, or about 0.01 V to about 1.25 V, or about 0.01 V to about 1 V, or about 0.05 V to about 0.9 V, or about 0.075 V to about 0.8 V, or about 0.1 V to about 0.7 V, or about 0.1 V to about 0.6 V, or about 0.1 V to about 0.5 V, or about 0.2 V to about 0.4 V. There are a variety of components known in the art that may be suited for use as the voltage source e.g., a voltage controller, a battery, and a voltage multiplier.

In some embodiments of the devices and methods as otherwise described herein, the drain current has a magnitude within the range of about 10⁻¹⁸ A to about 1 A, e.g., about 10⁻¹⁶ A to about 10⁻² A, or about 10⁻¹⁴ A to about 10⁻⁴ A, or about 10⁻¹² A to about 10⁻⁶ A, or about 10⁻¹⁰ A to about 10⁻⁶ A.

In some embodiments of the devices and methods as otherwise described herein, the device further comprises electronics configured to detect the magnitude of the drain current. One example of such a device is shown in schematic view in FIG. 4. Device 400 includes a substrate 410, a layer of BP NF 420, electrodes 430, a voltage source 440, and electronics 450. The person of ordinary skill in the art will appreciate that the electronics may comprise any component or combination of components that are capable of detecting the magnitude of the drain current, e.g., an ammeter. In some embodiments, the electronics configured to detect the magnitude of the drain current are incorporated together with the voltage source in a single device.

In some embodiments of the devices and methods as otherwise described herein, the electronics are further configured to correlate the magnitude of the drain current with a moisture level in an environment when the device is in fluid communication with the environment. The person of ordinary skill in the art will appreciate that the electronics may comprise any component or combination of components that are capable of correlating the magnitude of the drain current with a moisture level, for example, a processor configured to correlate the magnitude of the drain current with a moisture level (e.g., using a calibration curve), or an electrical circuit configured to correlate the magnitude of the drain current with a moisture level (e.g., using a calibration curve). In some embodiments, the electronics may include a moisture level indicator, e.g., one or more LED lights that correspond to a certain moisture level, an analog moisture level meter, a digital display, etc.

In operation, the sensing device may have a drain current, i.e., the current flowing between two electrodes upon the application of a voltage bias between them. The drain current may increase by at least three orders of magnitude as the relative humidity increases from 10% to 85%, at a temperature of, e.g., about 10° C., or about 15° C., or about 20° C., or about 25° C., or about 30° C., or about 35° C., or about 40° C., or about 45° C., or about 50° C.

In one example of a device of the present disclosure, a device for sensing moisture comprises a substrate, a surface comprising at least one atomic layer of BP NF disposed on the substrate, the at least one atomic layer of BP NF being in fluid communication with the exterior of the device, a first electrode disposed in electrical contact with the at least one atomic layer of BP NF, a second electrode disposed in electrical contact with the at least one atomic layer of BP NF, a voltage source configured to apply a voltage across the first electrode and the second electrode sufficient to cause a drain current to flow through the at least one atomic layer of black phosphorus nanoflakes, the drain current having a magnitude, and electronics configured to detect the magnitude of the drain current. The device may be specific to sensing humidity, exhibiting a selective response against water vapor. The BP NF used in the device may, e.g, be produced by liquid exfoliation through ultra-sonication. The BP NF film may be, e.g., between 10 nm and 1000 μm or more thick. Certain such examples may have, e.g., an estimated height reduction rate of about 2.7 nm/week for BP NF films in saturated relative humidity at 25° C. The person of ordinary skill in the art will appreciate that in certain such embodiments, it would take several years before the the device undergoes even a noticeable change in the thickness of the film of BP NF.

Another aspect of the disclosure described herein is a transistor comprising a substrate, a surface comprising a film of stacked black phosphorous nanoflakes disposed on the substrate, and a gate.

The person of ordinary skill in the art will appreciate, however, that in certain embodiments, the “gate” function of the transistor is the action of humidity on the film of black phosphorus nanoflakes, such that the film of black phosphorus nanoflakes allows more current to flow as the humidity is increased (i.e., due to a decrease in resistance in the film as humidity decreases). Accordingly, in other aspects of the disclosure, a transistor includes
a substrate;
a surface comprising a film of stacked black phosphorous nanoflakes disposed on the substrate; and
at least two electrodes comprising a first electrode and a second electrode, disposed in electrical contact with the film of stacked black phosphorus nanoflakes,
wherein the transistor is configured such that the electrical resistance between the first electrode and the second electrode decreases with an increase in humidity.

The transistor may be specific to sensing humidity, exhibiting a selective response against water vapor. The BP NF film used in the transistor may be, e.g., produced by liquid exfoliation through ultra-sonication. The transistor substrate may be flexible. In some embodiments, the substrate may comprise filter paper or a membrane filter, e.g., a polytetrafluoroethylene (PTFE) membrane filter.

In some embodiments of the devices and methods as otherwise described herein, the film of stacked BP NF is in fluid communication with the exterior of the device.

In some embodiments of the devices and methods as otherwise described herein, the transistor may further comprise at least two electrodes, e.g., two electrodes, or three electrodes, or four electrodes, etc. In some embodiments, the at least two electrodes may be two-probe electrical contacts. In some embodiments, the at least two electrodes are disposed in electrical contact with the at least one atomic layer of BP NF. A variety of suitable electrode materials are known in the art. In some embodiments, the at least two electrodes may be Gallium-Indium eutectic. In some embodiments, the at least two electrodes may comprise one or more of any suitable metal, e.g., gold, copper, tungsten, zinc, lead, silver, platinum, and palladium.

In some embodiments of the devices and methods as otherwise described herein, the at least two electrodes include a first electrode and a second electrode. In certain embodiments, the distance between the two electrodes is less than 2 cm, e.g., less than 1.75 cm, or less than 1.5 cm, or less than 1 cm, or less than 900 μm, or less than 800 μm, or less than 700 μm, or less than 600 μm, or less than 500 μm, or less than 400 μm, or less than 300 μm, or less than 200 μm, or less than 100 μm, or less than 75 μm, or less than 50 μm, or less than 25 μm, or less than 15 μm, or less than 10 μm, or less than 8 μm, or less than 6 μm, or less than 5 μm, or less than 4 μm, or less than pm, or less than 2 μm, or less than 1 μm.

The transistors and humidity sensors described herein may be configured such that a change in relative humidity causes a relatively large change in resistance. For example, in certain embodiments, a change in relative humidity of 20%, for example, from 40 to 60% (e.g., at 20° C., or in other embodiments at any temperature in the range of 10° C.-60° C.) causes an increase in resistance between a first electrode and a second electrode of at least five times, at least five times, or even at least ten times.

Another aspect of the disclosure described herein is a humidity sensor comprising a sensor chamber having an opening, and a device for sensing moisture as otherwise described herein, wherein the device is disposed within the chamber, and the chamber is in fluid communication with the opening.

One aspect of the disclosure described herein is a method for sensing moisture in an environment, the method comprising providing a device for sensing moisture as otherwise described herein, applying a voltage across the first electrode and the second electrode sufficient to cause a drain current to flow through the at least one atomic layer of BP NF, the drain current having a magnitude, and detecting the magnitude of the drain current. In some embodiments, the voltage applied is within the range of about 0.01 V to about 4 V, e.g., about 0.01 V to about 3.5 V, or about 0.01 to about 3 V, or about 0.01 V to about 2.5 V, or about 0.01 V to about 2 V, or about 0.01 V to about 1.75 V, or about 0.01 V to about 1.5 V, or about 0.01 V to about 1.25 V, or about 0.01 V to about 1 V, or about 0.05 V to about 0.9 V, or about 0.075 V to about 8 V, or about 0.1 V to about 7 V, or about 0.1 V to about 0.6 V, or about 0.1 V to about 0.5 V, or about 0.2 V to about 0.4 V. In some embodiments of the devices and methods as otherwise described herein, the drain current has a magnitude within the range of about 10⁻¹⁸ A to about 1 A, e.g., about 10⁻¹⁶ A to about 10⁻² A, or about 10⁻¹⁴ A to about 10⁻⁴ A, or about 10⁻¹² A to about 10⁻⁶ A, or about 10⁻¹⁰ A to about 10⁻⁶ A.

Methods as described herein can further include determining a moisture level in the environment based on the magnitude of the drain current. The person of ordinary skill in the art will appreciate that any suitable set of electronics can do this, e.g., a general purpose processor programmed to determine the moisture level, or a processor or other circuit specially configured to determine the moisture level.

Another aspect of the disclosure described herein is a method for switching a transistor gate, the method comprising providing a transistor in fluid communication with an environment with a moisture level, the transistor as otherwise described herein, applying a voltage across the first electrode and the second electrode sufficient to cause a drain current to flow through the film of stacked BP NF, the drain current having a magnitude, and altering the level of moisture sufficiently to alter the magnitude of the drain current.

### EXAMPLES

The Examples that follow are illustrative of specific embodiments of the invention, and various uses thereof. They are set forth for explanatory purposes only, and are not to be taken as limiting the invention.

### Example 1. Black Phosphorus Film Preparation

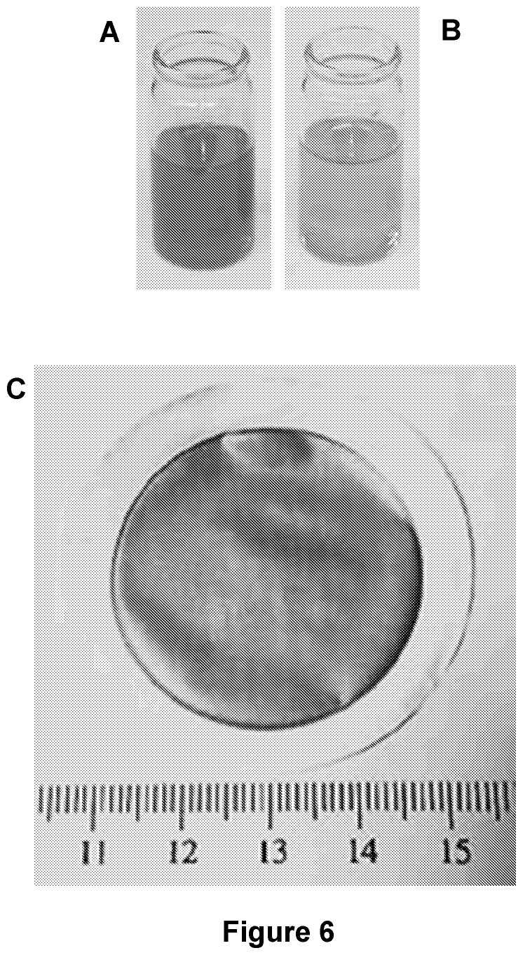

Black phosphorus (BP) nanoflake (NF) films were prepared by liquid exfoliation. 15 mg of bulk BP was ground and immersed in 20 mL of an appropriate aprotic, polar solvent (DMF or DMSO). The samples were sonicated for 12 hours to provide a suspension shown in FIG. 6A, and then centrifuged for 30 minutes to provide the material shown in FIG. 6B. The top 90% of the supernatant was collected. While the use of DMF produces thinner flakes, DMSO can also produce similar results, and may be preferable due to its lower toxicity. The prepared solutions are then vacuum filtered on a hydrophilic PTFE membrane filter with a 0.1 μm pore size and thoroughly washed with ethanol and isopropyl alcohol (IPA) to remove the solvent residue. The resulting layer of black phosphorus nanoflakes on the PTFE filter is shown in FIG. 6C.

### Example 2. SEM and Raman Characterization of Black Phosphorus Films

Wet films prepared according to Example 1 were immersed in IPA, sonicated to separate flakes from the film, and then re-filtered on a mixed cellulose membrane filter. The films were cooled in liquid nitrogen to enhance fragility, and then broken to access an intact cross-sectional view.

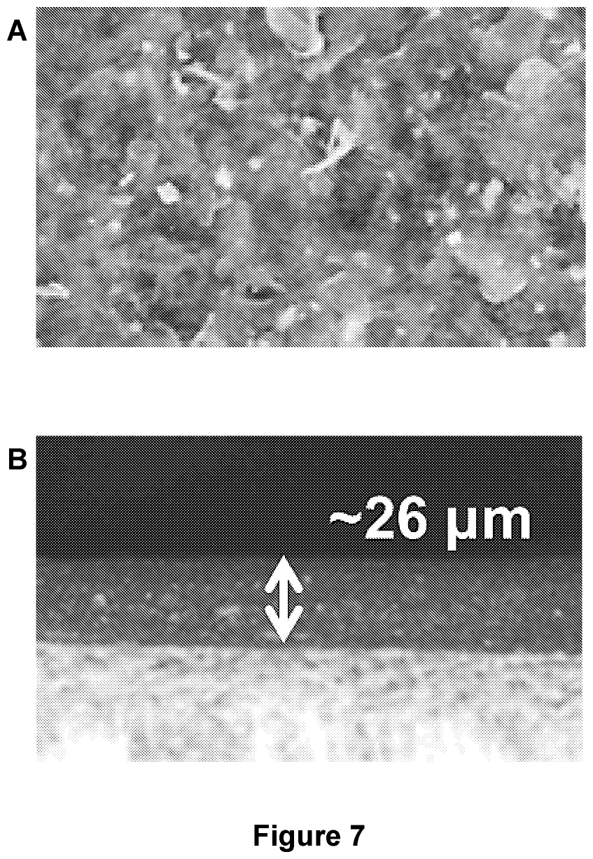

Scanning electron microscopy (SEM) images of the stacked BP NF on the membrane filter show densely packed and uniformly distributed BP NF (See, FIG. 7A. FIG. 7B shows the cross-section SEM view of a film made by filtering 3 mL of DMF solution prepared according to Example 1 with an estimated thickness of ˜26 μm.

Raman spectra of the BP NF films were acquired with a HORIBA LabRAM HR Evolution confocal Raman microscope. The instrument was configured with a 532 nm laser source, 1200 g/mm grating, a Horiba Synapse OE CCD detector, and either a 50× or 100× objective. Laser powers at the sample were between 1-15 mW. Integration times and averaging parameters were chosen to maximize signal-to-noise while minimizing any sample degradation.

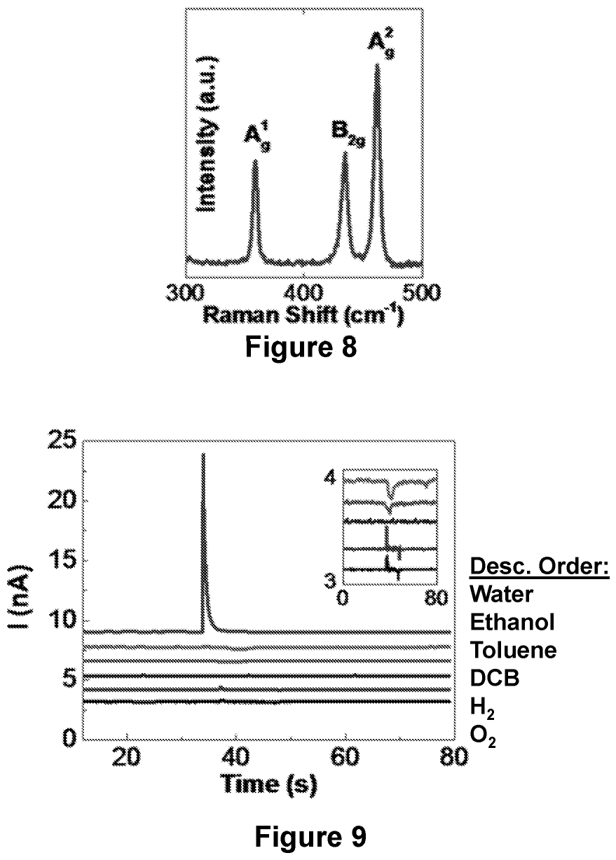

Raman spectra (See, FIG. 8) showed three typical sharp BP spectral peaks—A_{g}¹ (out-of-plane mode), B_{2g} and A_{g}² (in-plane modes) were observed at wavenumbers of ˜360 cm⁻¹, ˜437 cm⁻¹, and ˜466 cm⁻¹, respectively. These peaks are consistent with the signature spectrum of bulk BP, suggesting that the flakes remain in the crystalline phase after exfoliation. TEM imaging on similarly produced nanoflakes, reported elsewhere (Yasaei et al., “High-Quality Black Phosphorus Atomic Layers by Liquid-Phase Exfoliation,” Adv. Mater. 27(11):1887-92 (2015), which is hereby incorporated herein by reference in its entirety), support this conclusion.

### Example 3. Black Phosphorus Film Sensing Performance

Wet films prepared according to Example 1 were dried under vacuum and cut into pieces of the desired size. Two-probe electrical contacts were established using Gallium-Indium (Ga—In) eutectic (See, FIG. 5C). The production of such devices could be scaled up easily, e.g., by producing larger amounts of BP dispersions, performing the vacuum filtration in a larger setup, and by utilizing Ga—In printing methods.

Sensing experiments were carried out in either dynamic (pulse injection) or static (closed chamber) setups. The injection unit of a gas chromatography system (HP 6890) was used to inject a known volume (0.2 to 5 μL) of the analytes with a 400 to 5000 split ratio. In static experiments, a constant humidity was initially generated in a custom-made environmental chamber equipped with a reference humidity/temperature sensor (Si7005, Silicon Labs). The sensor was then loaded, the chamber was sealed, and the responses of the BP NF film and reference sensor were simultaneously recorded.

FIG. 9 shows a typical current modulation of the BP NF device in response to injection of 2 nL of selected chemicals including water vapor, alcohols (ethanol, isopropanol), ketones (toluene, acetone), and benzenes (dichlorobenzene) at a constant (DC) applied bias of 0.5 V in identical experimental conditions. A ˜5 fold enhancement in the drain current was observed upon injection of the water vapor, while the response to all other tested analytes was at least two orders of magnitude smaller. Also, the sensors showed negligible response upon exposure to direct flow of hydrogen (H₂), oxygen (O₂), and carbon dioxide (CO₂) gases, tested at up to 20 standard cubic centimeters per minute (sccm). The response of the films fully recovers within 1-5 seconds of the injection, depending on the volume of the water vapor pulse. The selectivity and fast response time suggest that devices comprising BP NF films would be highly practical moisture sensors (i.e., by minimizing cross-sensitivity and false-positives).

### Example 4. Film Sensing Performance Comparison

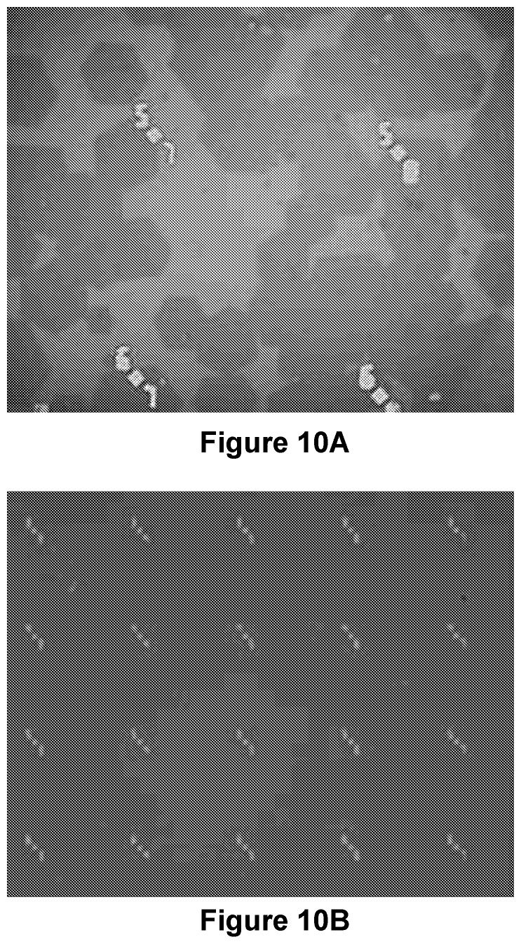

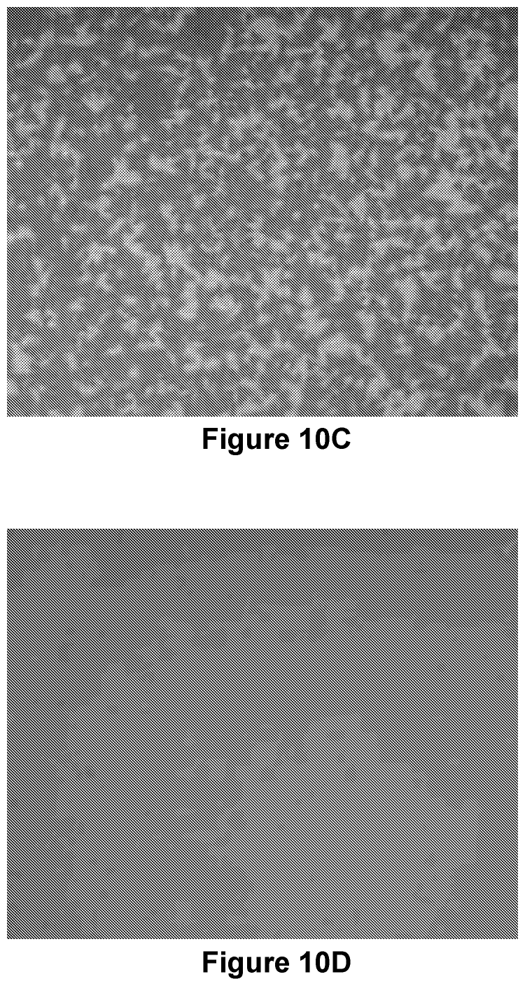

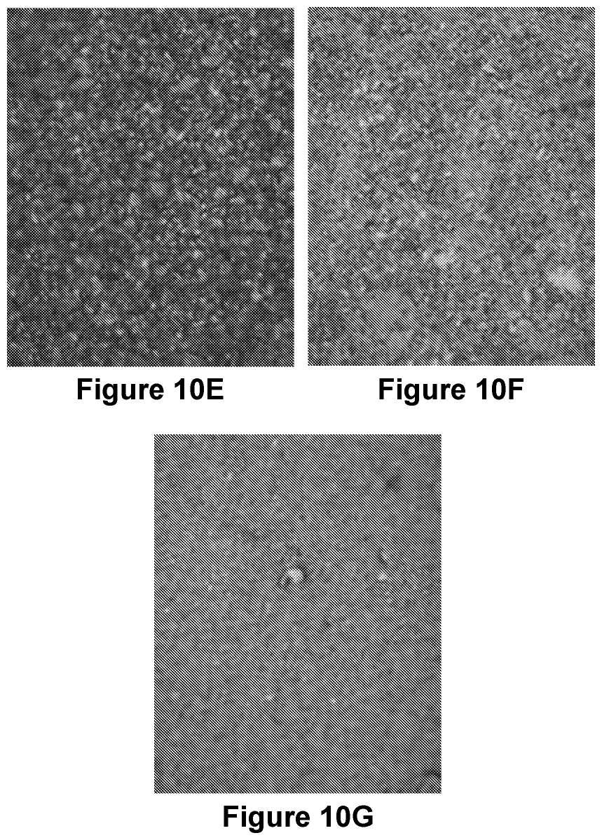

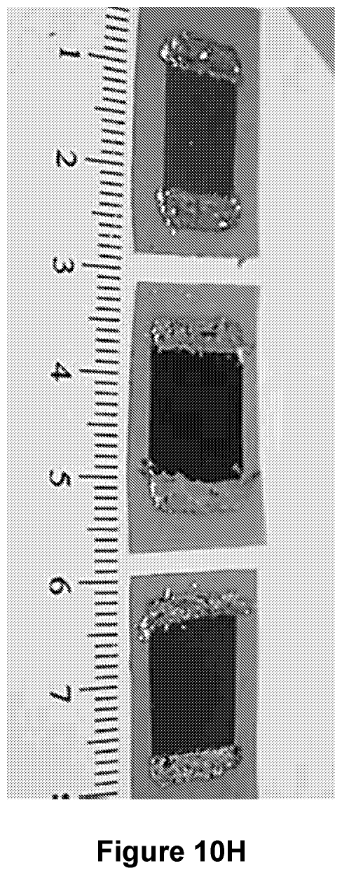

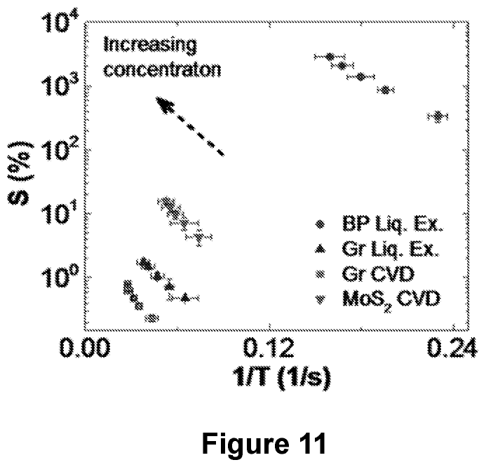

The water vapor sensing characteristics of BP films were compared to those of polycrystalline monolayer graphene (grown in an atmospheric pressure CVD process), and molybdenum disulfide (MoS₂) grown by chemical vapor deposition, as well as graphene and MoS₂ films of stacked flakes made by liquid exfoliation according to Example 1 (See, FIG. 10), using N-Methyl-2-pyrrolidone (NMP) and isopropyl alcohol (IPA) as the solvents for graphene and MoS₂, respectively. For the device preparation, the grown films were transferred on fresh Si/SiO₂ substrates by a polymer-assisted wet etch method and gold electrodes are patterned to establish electrical contacts, shown in image (H). FIG. 11 shows the sensitivity (defined as

$$S = \frac{I - {I}_{0}}{{I}_{0}} \% )$$

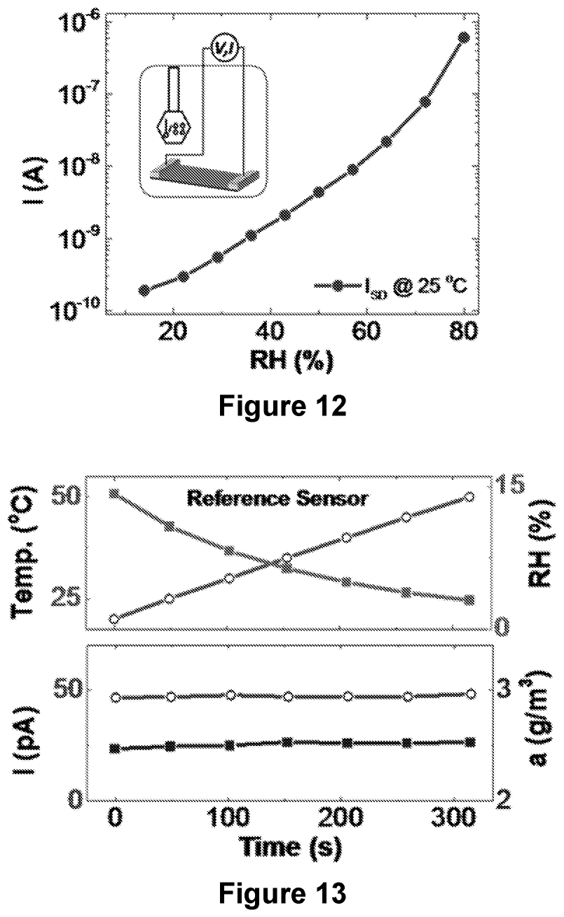

for these sensors with respect to reciprocal recovery time (1/T) upon injection of 0.5 to 12.5 nl of water vapor. The results for films of stacked MoS₂ NF were not included in FIG. 11, as a noticeable response was not observed for the range of concentrations used in this Example. Under identical conditions, BP NF devices exhibited more than two orders of magnitude higher sensitivity and a more than two-fold faster recovery in comparison to all other tested nanomaterial-based sensors. The performance of BP films was also tested in a custom made environmental chamber with reference temperature and humidity sensors. As shown in FIG. 12, the drain current of the sensor increased by ˜4 orders of magnitude as the relative humidity (RH) was varied from 10% to 85%, demonstrating a level of sensitivity among the highest reported for humidity sensors.

### Example 5. Black Phosphorus Film Temperature and Pressure Dependence Characterization

Because RH strongly correlates with temperature, the temperature-dependent response of the humidity sensors was carefully characterized. FIG. 13 (top) shows the temperature and RH relationship as measured by a commercial reference sensor. To study the temperature effect, the absolute humidity of the chamber was held constant (sealed chamber) while the temperature was varied from 20° C. to 50° C. The BP film was shown to be insensitive to temperature. However, a strong correlation was observed between the absolute humidity and the response of the sensors as shown in FIG. 13 (bottom), further confirming the selectivity of BP film against humidity.

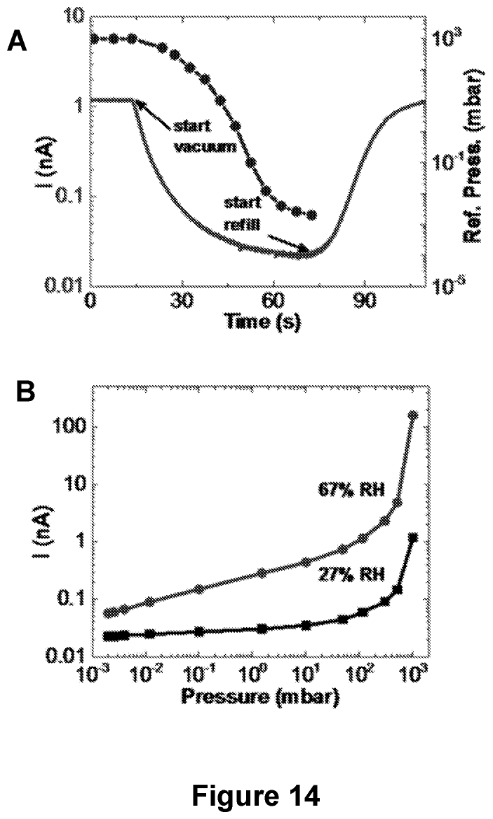

The performance of BP films with respect to the pressure of humid air was also tested. FIG. 14A shows the time dependent response of a BP film loaded in a vacuum chamber (lower line) as well as the pressure of the chamber measured by a reference digital vacuum gauge (upper line) during an evacuation and refill cycle. Through these simultaneous measurements, the response of the sensor with respect to pressure was extracted and shown in FIG. 14B for RH levels of 27% and 67%. Since the response of the sensor arises from the moisture content in the environment, the extrapolated intersection of these two curves at ˜2×10⁻⁵ mbar gives an approximation for the pressure detection limit of the BP film sensors. The combination of wide-range detection capability (˜2×10⁻⁵ to 10³ mbar) and high sensitivity suggest that BP films may be useful for trace-level humidity measurements in low pressure systems.

### Example 6. Black Phosphorus Films Mechanistic Study

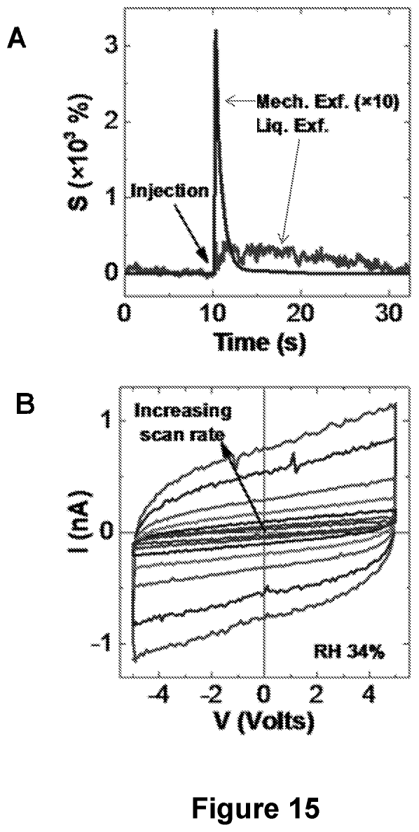

A set of experiments to gain insight into the operational principles of the BP films was performed. In general, the sensing mechanism in humidity sensors is associated with either: (i) modulation in the electronic conduction due to a charge transfer between the analytes and the sensor surface (doping effect), (ii) modulation in the ionic conduction upon formation of a capillary condensed electrolytic media, or (iii) modulation in the capacitance of the sensor due to structural modification or change in the dielectric properties of the sensing material. In homogenous sensing media such as individual flake devices, the first case is naturally the governing mechanism, while any scenario could govern the operation of heterogeneous and porous sensors such as films of stacked flakes or composite structures. With this perspective, the sensing performance of the BP NF devices was compared to that of mechanically exfoliated individual flakes. FIG. 15A shows the magnified (×10) sensing response of an individual BP flake and the response of a BP film sensor upon exposure to an identical water vapor pulse injection. As clearly illustrated, the sensing response of the individual flake device is ˜80 times smaller, indicating that the charge transfer to flakes and metal contacts (doping) is not the governing mechanism in the BP films.

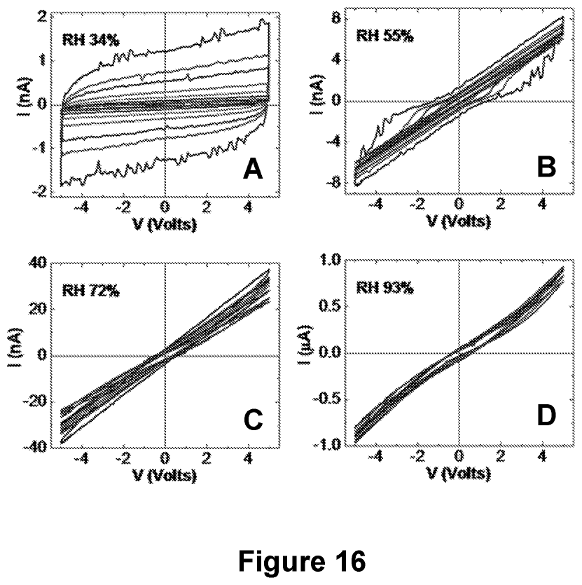

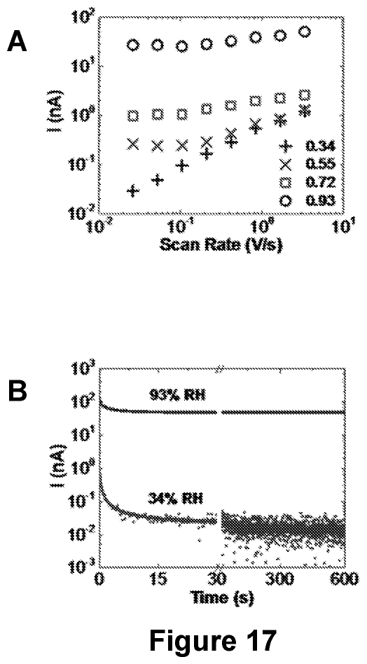

Cyclic current-voltage (I-V) experiments in different RH levels were performed, demonstrating a scan-rate dependency (FIG. 15B), which is a characteristic of charge storage and capacitive behavior. The slope of the linear region corresponds to a resistive contribution. FIGS. 16A-D are graphs showing the I-V characteristics of a BP NF film sensor at different RH in several different scan rates. In lower humidity levels, the response is remarkably affected by changing the scan rate, suggesting that the capacitance is dominant. In high RH, the response is just slightly affected at different scan rates, suggesting the dominance of the resistive contribution. The response of the BP device to an applied step voltage is an exponential decay with slow time constants, similar to the response of electrochemical capacitors. Thus, as the humidity increased, the slope of the I-V trend increased, but the hysteresis became less dependent on the scan rate. This behavior perfectly resembles the characteristics of non-ideal (commercial) electrochemical capacitors. Moreover, the response of the film to a step voltage is an exponential decay current with a residual leakage, as observed in electrochemical systems (See FIG. 17B). In such cases, the capacitive response is associated with the formation of the electric double layer (EDL) on the surface of the flakes, and the residual leakage current corresponds to ionic charge transfer.

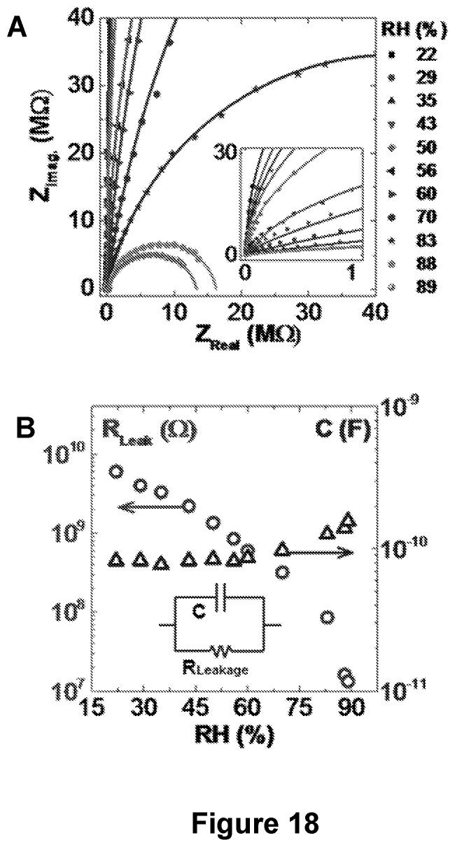

To better understand the effects of resistive and capacitive contributions on the overall response of the BP film sensors, impedance spectroscopy (IS) experiments were performed by sweeping the frequency from 100 Hz to 10 MHz. As shown in FIG. 18A, a semicircular trend was observed in the Nyquist representation of the results, which can be fitted by the response of a parallel RC circuit (See, FIG. 16B, inset). The equivalent series resistance (ESR) compared with the leakage (charge transfer) resistance in the IS results is notably smaller, hence a parallel RC circuit (See, FIG. 16B, inset) can sufficiently model the experimental data. FIG. 18B shows the modulation of the resistance and capacitance in the modeled equivalent circuit as a function of RH. It was observed that as the RH increased from 20% to 90%, the resistance decreased more than 450 times, while the capacitance only varied by less than twofold. These results suggest that ionic conduction through the absorbed moisture medium is the dominant mechanism of current modulation in the BP film sensors.

BP flakes were shown to efficiently absorb the ambient moisture and form a layer of liquid on the surface of the flakes, which can potentially be ionic conductive. The hydrophilicity of BP flakes is also an ideal characteristic for humidity detection, as it facilitates the formation a uniform layer of moisture media for ion hopping. Additionally, BP flakes were shown to react with humid air and form phosphorus oxides, which can produce acids in exposure to water molecules. In principle, the acids can ionically dissolve in the moist media and enhance the concentration of mobile H+ ions. Thus, water auto ionization and ionic solvation of the phosphorus oxoacids in the moist absorbed layer deliver the required ions for the charge transfer process.

### Example 7. Film Stability and Degradation Rates

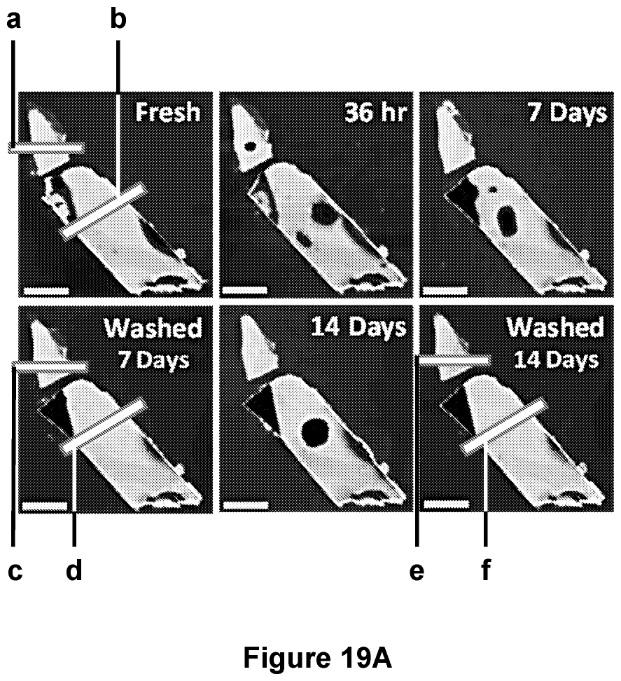

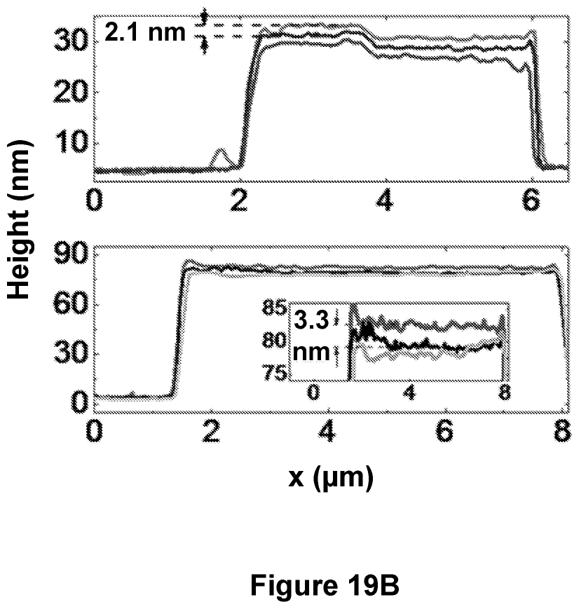

A set of experiments to find the degradation rate of the sensors in high humidity environments was performed. The morphology of the flakes in a saturated humidity (100% RH) environment at room temperature was measured at different time intervals (FIG. 19A). For precise thickness measurements, large, mechanically exfoliated BP flakes with smooth surfaces on a polished silicon oxide (SiO₂) substrate were used. AFM topology maps (FIG. 19A) indicated that water bubbles started to form on top of the flakes and migrated to coalesce, forming larger bubbles. After one week, the sample was thoroughly washed, then dried under a nitrogen flow. The flakes were then immediately mapped by AFM (FIG. 19A—7 days). The same process was also repeated after two weeks. The height profiles of the fresh flakes as well as the washed samples (one and two weeks exposed are shown in FIG. 19B, indicating an estimated height reduction rate of 2.7±0.6 nm/week for BP flakes in saturated RH at 25° C. Assuming a typical thickness of 25 μm for the sensors, it would take several years for a BP NF film to undergo a noticeable change in its thickness. These results suggest that, in the film thicknesses that would be used in a moisture sensing device, BP NF film degradation would not significantly affect device lifetimes.

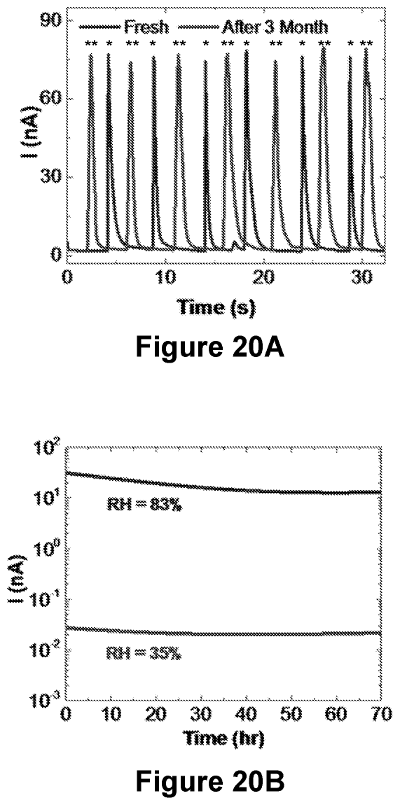

The stability of the sensing response in BP film sensors was also explored over extended periods. FIG. 20A shows the pulse injection response of a sensor immediately after fabrication, and also after 3 month exposure to ambient conditions (25° C. and 25±12% RH). It is shown that the response characteristics of the sensor remain almost unchanged after 3 months exposure to ambient conditions. These results suggest that humidity sensing devices comprising BP NF films would be highly effective for several months, without a noticeable drift in sensing performance.

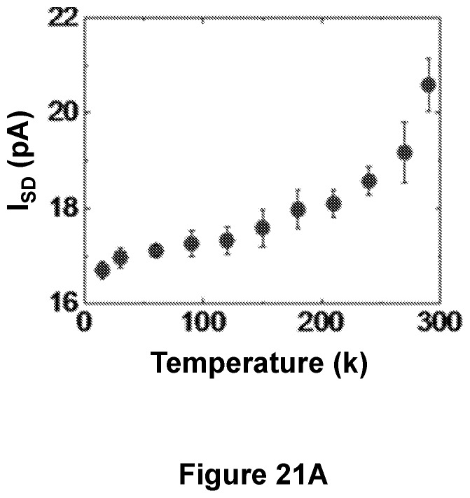

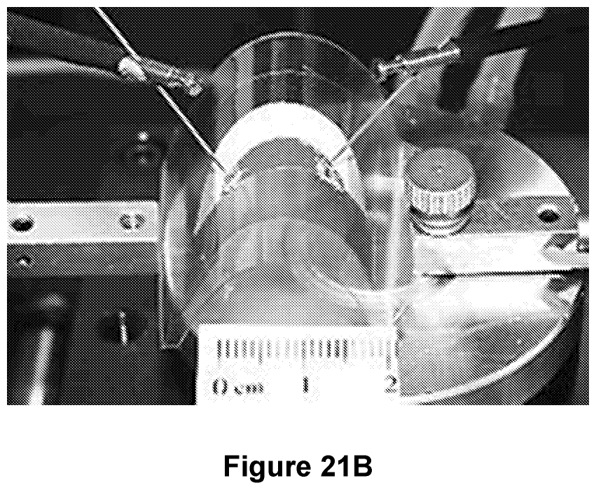

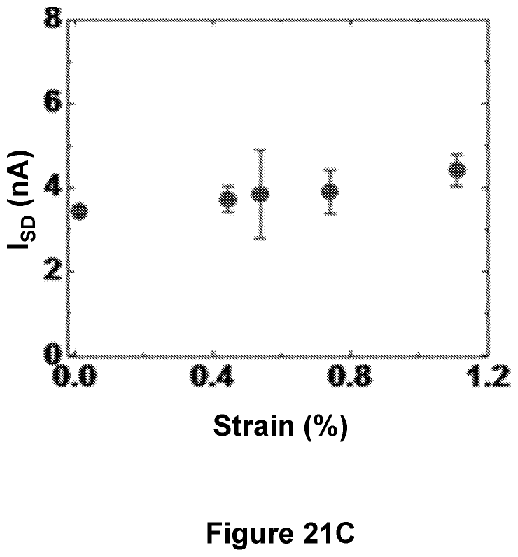

Additionally, the drift of the sensors under continuous operation was tested. In drift tests, saturated solution of potassium chloride (KCl) and magnesium chloride (MgCl₂) were loaded into the chamber, which yielded the constant relative humidity (RH) of 83% and 35% in room temperature, respectively. As shown in FIG. 20B, the current drift of the sensor was tested at constant humidity levels of 35% and 83% RH, both at 25° C., for over 72 hours. The polarity of the applied voltage was switched every 15 minutes to rule out the capacitive response (current decay) of the sensor from the drift in the response. The results demonstrated that the response of the sensor remained fairly stable, even in harsh environments and under applied potential. The response of the BP films was also tested at different temperatures and applied bending strains (See, FIG. 21), showing just a minor dependence, suggesting that BP film sensors can be utilized in a wide range of temperatures and in flexible and wearable applications.

### Example 8

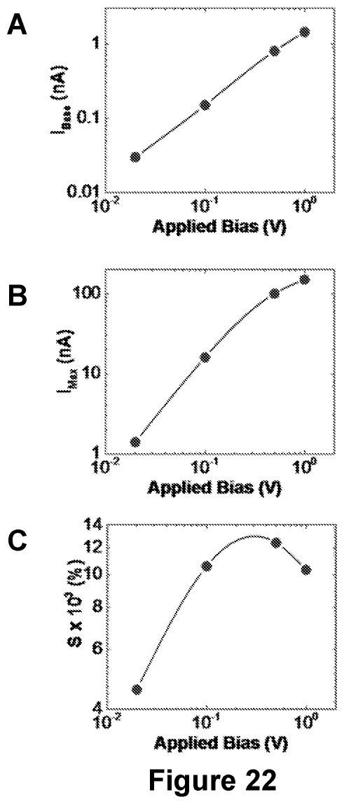

The baseline and maximum value of the drain current in operation of a BP film sensor was examined at different applied voltages. The base current increases linearly, but the maximum current deviates from a linear trend in large voltages above 0.5 V (See, FIGS. 22A and 22B). The optimum operation voltage (in terms of maximum sensitivity) is found to be 0.2-0.4 V. See FIG. 22C.

The above Examples demonstrate the application of films of stacked BP NF for highly sensitive and selective humidity detection as well as pressure measurement of humid. Results revealed that the degradation rate of BP flakes in saturated humidity is reasonably slow, allowing BP thin films and composites to be used in many scenarios in which the devices may be exposed to harsh ambient conditions, including energy storage, catalysis, chemical and bio-sensing applications, with years of effective lifetime.

It is understood that the examples and embodiments described herein are for illustrative purposes only and that various modifications or changes in light thereof will be suggested to persons skilled in the art and are to be incorporated within the spirit and purview of this application and scope of the appended claims.

1-45. (canceled)

46. A device for sensing moisture, the device comprising
a substrate; and
a surface comprising at least one atomic layer of black phosphorus nanoflakes disposed on the substrate,
wherein the sensing device is specific to sensing humidity, exhibiting a selective response against water vapor.

47. The device of claim 46, wherein the at least one atomic layer of black phosphorus nanoflakes is in fluid communication with the exterior of the device.

48. The device of claim 46, further comprising at least two electrodes disposed in electrical contact with the at least one atomic layer of black phosphorus nanoflakes.

49. The device of claim 48, wherein the at least two electrodes include a first electrode and a second electrode, and wherein the distance between the first electrode and the second electrode is less than 10 microns.

50. The device of claim 48, wherein the at least two electrodes include a first electrode and a second electrode, and wherein the distance between the first electrode and the second electrode is less than 1 micron.

51. The device of claim 48, wherein the at least two electrodes include a first electrode and a second electrode, and where the device further comprises a voltage source configured to apply a voltage across the first electrode and the second electrode sufficient to cause a drain current to flow through the at least one atomic layer of black phosphorus nanoflakes, wherein the drain current has a magnitude, and wherein the device further comprises electronics configured to detect the magnitude of the drain current and to correlate the magnitude of the drain current with a moisture level in an environment when the at least one atomic layer of black phosphorus nanoflakes is in fluid communication with the environment.

52. The device of claim 51, wherein the voltage source is configured to apply a voltage within the range of about 0.01 V to about 4 V.

53. The device of claim 46, wherein a drain current resulting from the application of a voltage at a relative humidity of 85% is at least three orders of magnitude greater than a drain current measured at a relative humidity of 10%.

54. The device of claim 46, wherein the at least one atomic layer of black phosphorus nanoflakes comprises a film of stacked black phosphorus nanoflakes disposed on the substrate.

55. The device of claim 46, comprising
a substrate;
a surface comprising at least one atomic layer of black phosphorus nanoflakes disposed on the substrate, the at least one atomic layer of black phosphorus nanoflakes being in fluid communication with the exterior of the device;
a first electrode disposed in electrical contact with the at least one atomic layer of black phosphorus nanoflakes;
a second electrode disposed in electrical contact with the at least one atomic layer of black phosphorus nanoflakes;
a voltage source configured to apply a voltage across the first electrode and the second electrode sufficient to cause a drain current to flow through the at least one atomic layer of black phosphorus nanoflakes, the drain current having a magnitude; and
electronics configured to detect the magnitude of the drain current.

56. A humidity sensor comprising
a sensor chamber having an opening; and
the device of claim 46;
wherein the device is disposed within the chamber, and the chamber is in fluid communication with the opening.

57. A device of claim 46, configured such that a change in relative humidity of from 40 to 60% at 20° C. causes an increase in resistance between a first electrode and a second electrode of at least five times, at least five times, or even at least ten times.

58. A method for sensing moisture in an environment, the method comprising
providing the device of claim 46;
applying a voltage across a first electrode and a second electrode sufficient to cause a drain current to flow through the at least one atomic layer of black phosphorus nanoflakes, the drain current having a magnitude; and
detecting the magnitude of the drain current.

59. The method according to claim 58, wherein the distance between the first electrode and the second electrode is less than 10 microns.

60. The method according to claim 58, wherein the voltage is within the range of about 0.01 V to about 4 V.

61. A transistor comprising
substrate;
a surface comprising a film of stacked black phosphorous nanoflakes disposed on the substrate; and
at least two electrodes comprising a first electrode and a second electrode, disposed in electrical contact with the film of stacked black phosphorus nanoflakes,
wherein the transistor is configured such that the electrical resistance between the first electrode and the second electrode decreases with an increase in humidity.

62. The transistor of claim 61, wherein the film of stacked black phosphorus nanoflakes is in fluid communication with the exterior of the transistor.

63. The transistor of claim 61, wherein the at least two electrodes include a first electrode and a second electrode, and wherein the distance between the first electrode and the second electrode is less than 10 microns.

64. A method for switching a transistor, the method comprising
providing a transistor of claim 61 in fluid communication with an environment with a moisture level:
applying a voltage across the first electrode and the second electrode sufficient to cause a drain current to flow through the film of stacked black phosphorus nanoflakes, the drain current having a magnitude; and
allowing the level of moisture to change sufficiently to alter the magnitude of the drain current.

65. The method according to claim 64, wherein the distance between the first electrode and the second electrode is less than 1 micron.
